(19) United States
(12) Patent Application Publication
(10) Pub. No.: US 2013/0258591 A1
(43) Pub. Date: Oct. 3, 2013

(54) AIR DAM MODULE AND ELECTRONIC DEVICE HAVING THE SAME

(71) Applicants: ZHENG-HENG SUN, Tu-Cheng (TW); LEI LIU, Shenzhen City (CN); SHU-NI YI, Shenzhen City (CN); PING-CHUAN DENG, Shenzhen City (CN)

(72) Inventors: ZHENG-HENG SUN, Tu-Cheng (TW); LEI LIU, Shenzhen City (CN); SHU-NI YI, Shenzhen City (CN); PING-CHUAN DENG, Shenzhen City (CN)

(73) Assignees: HON HAI PRECISION INDUSTRY CO.. LTD., Tu-Cheng (TW); HONG FU JIN PRECISION INDUSTRY (ShenZhen) CO., LTD., Shenzhen City (CN)

(21) Appl. No.: 13/564,739

(22) Filed: Aug. 2, 2012

(30) Foreign Application Priority Data
Mar. 29, 2012 (CN) 201210087533.9

(51) Int. Cl. F16K 17/12; H05K 7/20

(52) U.S. Cl. 361/695; 361/690; 137/527.8

(57) ABSTRACT

An electronic device includes an air dam module. The air dam module includes a frame and a rotating member. The frame defines a vent. The rotating member is received in the vent and includes a pivot rotatably connected to midpoints of opposite sides of the frame, a first shield plate extending up from a top side of the pivot, to vertically block an upper half of the vent. In addition, a second shield plate heavier than the first shield plate and extending down from a bottom side of the pivot, to vertically block a lower half of the vent by gravity.

### BACKGROUND

1. Technical Field

The present disclosure relates to an electronic device including an air dam module.

2. Description of Related Art

Fans are mounted in an electronic device for dissipating heat from electronic components in the electronic device. However, when a fan is broken, air pressure in the electronic device changes, which will cause air back flowing and turbulence, adversely influencing heat dissipation from the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, assembled, isometric view of an exemplary embodiment of an electronic device, wherein the electronic device includes a plurality of air dam modules.

FIG. 2 is an exploded, isometric view of one of the air dam modules of FIG. 1.

FIGS. 3 and 4 are assembled, isometric views of the air dam module of FIG. 2 from different perspectives, and in different states.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

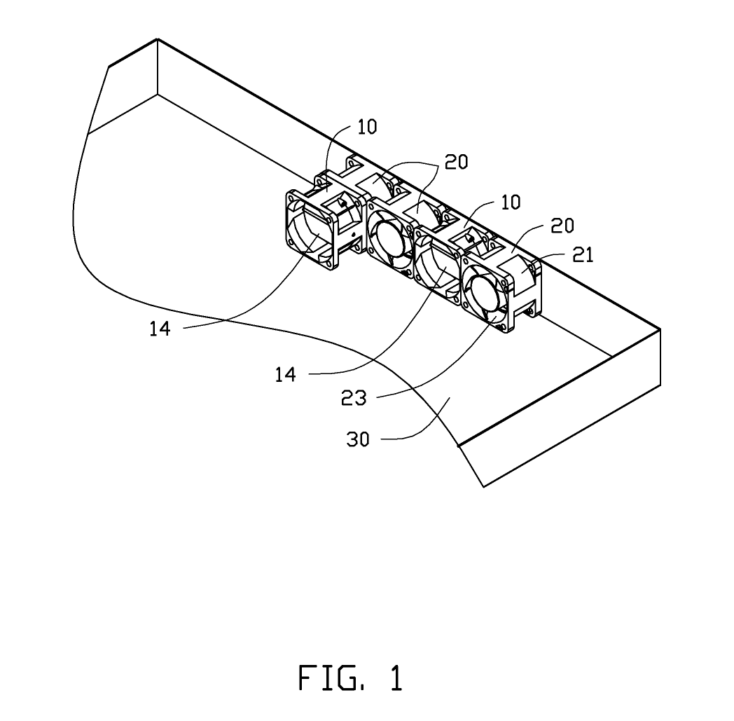

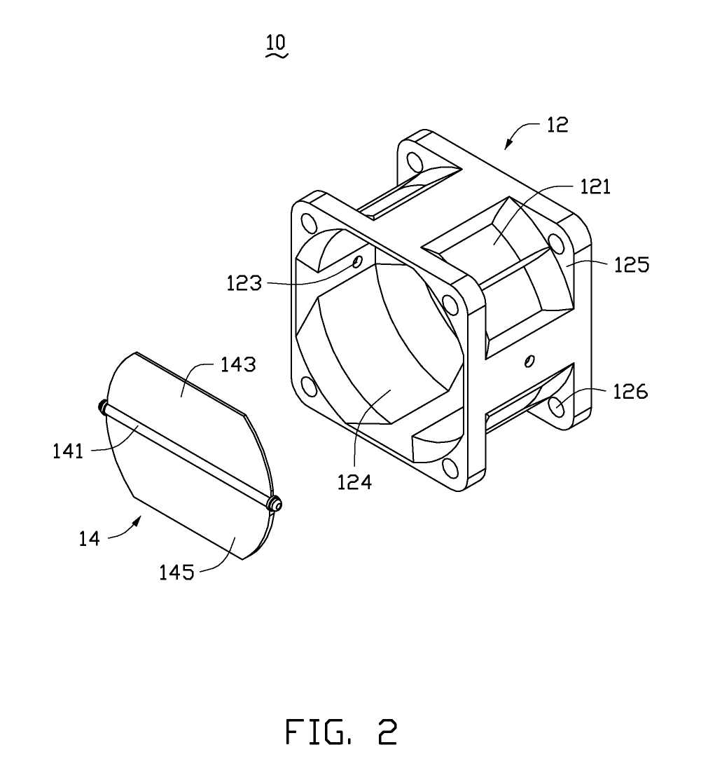

FIGS. 1 and 2 show an exemplary embodiment of an electronic device. The electronic device includes a chassis 30, a plurality of standard fans 20, and a plurality of air dam modules 10.

Each standard fan 20 includes a first frame 21 defining a first vent 23 having a substantially circular cross section.

Each air dam module 10 includes a second frame 12 and a rotating member 14.

The second frame 12 has the same shape and size as the first frame 21 of each standard fan 20. The second frame 12 includes a columnar main body 121, and two fixing plates 125 at front and rear ends of the main body 121. A second vent 124 having a substantially circular cross section is axially defined in the main body 121, extending through the fixing plates 125. A cross-sectional area of the second vent 124 is equal to a cross-sectional area of the first vent 23 of each standard fan 20. Four fixing holes 126 are defined in the four corners of each fixing plate 125. Therefore, the second frame 12 has the same manner of mounting as the standard fans 20. Midpoints of opposite sides of the main body 121 each define a pivot hole 123 communicating with the second vent 124.

The rotating member 14 includes a horizontal pivot 141, a first shield plate 143 extending up from a top side of the pivot 141, and a second shield plate 145 extending down from a bottom side of the pivot 141. The first and second shield plates 143 and 145 are symmetrical about the pivot 141, and are arranged substantially on a same plane. Opposite ends of the first and second shield plates 143 and 145 are arc-shaped, and are arranged on an arc of a circle centered around a midpoint of the pivot 141. Opposite ends of the pivot 141 protrude out of the opposite ends of the first and second shield plates 143 and 145. The thickness and the weight of the second shield plate 145 are greater than the thickness and the weight of the first shield plate 143. A perpendicular distance between the top side of the first shield plate 143 and the bottom side of the second shield plate 145 is not more than a perpendicular distance between the front end and the rear end of the second frame 12.

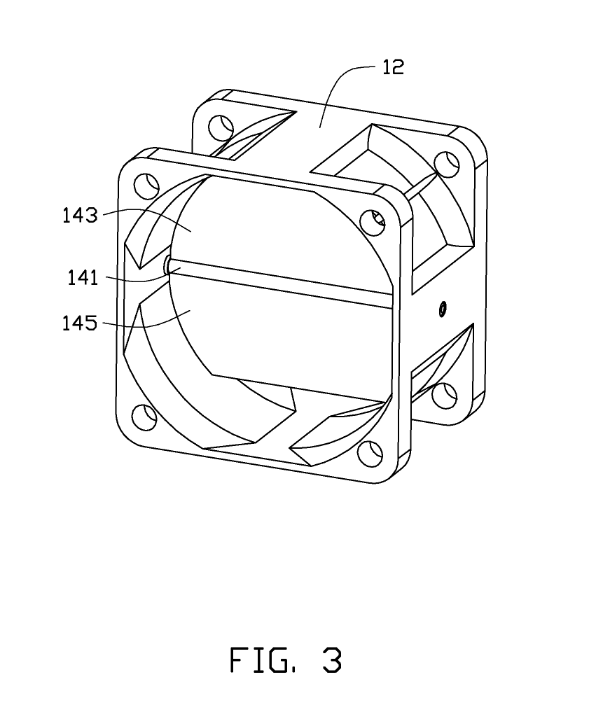

As shown in FIG. 3, to assemble one air dam module 10, the pivot 141 is deformed to be received in the second vent 124, to allow the opposite ends of the pivot 141 to align with the pivot holes 123. The pivot 141 is restored, to allow the opposite ends of the pivot 141 to rotatably engage in the pivot holes 123. Thereby, the rotating member 14 is rotatably received and held captive in the second vent 124. The second shield plate 145 hangs vertically under the pivot 141 with gravity, and blocks the lower half of the second vent 124. The first shield plate 143 is vertically arranged on the pivot 141, and blocks the upper half of the second vent 124. The opposite ends of the first and second shield plates 143 and 145 abut inner surfaces of the opposite sides of the main body 121.

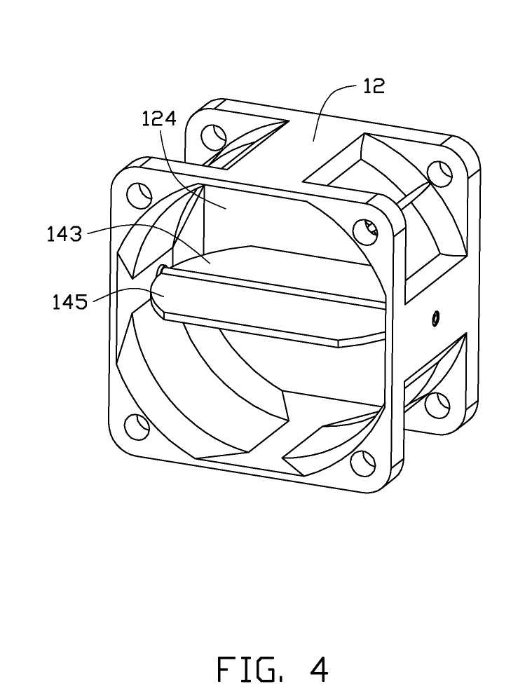

As shown in FIG. 4, when airflow from a standard fan 20 is blown forward towards the air dam module 10, the second shield plate 145 rotates forward 90 degrees around the pivot holes 123, and the first shield plate 143 rotates backward 90 degrees around the pivot holes 123. The rotating member 14 is completely received in the second vent 124 all the time, and will never extend out of the second frame 12 to take up outside space.

As shown in FIG. 1, before a replacement of a broken standard fan 20 in the chassis 30 is completed, an air dam module 10 can replace the broken down standard fan 20 to be mounted in the chassis 30. The rotating member 14 is vertical by means of gravity, and so blocks the second vent 124. Air pressure at the air dam module 10 will not change substanially, so the rotating member 14 can prevent air back flowing towards the air dam module 10.

If there is enough space in the chassis 30, an air dam module 10 can be mounted to a front end of a standard fan 20. When the standard fan 20 operates, the rotating member 14 is blown by the standard fan 20 to rotate 90 degrees, to allow the airflow produced by the standard fan 20 to pass through the second vent 124. When the standard fan 20 is broken-down, the rotating member 14 is vertically arranged in the air dam module 10 by gravity, and blocks the second vent 124, which will prevent air back flowing towards the air dam module 10.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An air dam module, comprising:
a frame defining a vent through a front end and a rear end of the frame; and
a rotating member received in the vent, and comprising a horizontal pivot, a first shield plate extending up from a top side of the pivot, and a second shield plate heavier than the first shield plate extending down from a bottom side of the pivot, wherein opposite ends of the pivot are rotatably connected to midpoints of opposite sides of the frame, and upon a condition that the gravity of the second shield plate is not overcome by an airflow passing through the vent, the gravity of the second shield plate causes the rotating member to rotatably stay in a position where the second shield plate vertically blocks a lower half of the vent and the first shield plate vertically blocks an upper half of the vent.

2. The air dam module of claim 1, wherein the first and second shield plates are symmetrical about the pivot, and are arranged substantially on a same plane.

3. The air dam module of claim 2, wherein the vent defines a substantially circular cross section, opposite ends of the first and second shield plates are arc-shaped, and are arranged on an arc of a circle centered around a midpoint of the pivot.

4. The air dam module of claim 3, wherein the opposite ends of the first and second shield plates abut inner surfaces of the opposite sides of the frame, in response to the rotating member vertically blocking the vent.

5. The air dam module of claim 1, wherein a perpendicular distance between a top side of the first shield plate and a bottom side of the second shield plate is not more than a perpendicular distance between the front end and the rear end of the frame.

6. An electronic device, comprising:
a chassis; and
an air dam module comprising a frame mounted to the chassis and defining a vent extending from front to back, wherein the frame has the same shape and size as a standard fan, the air dam module comprises a rotating member received in the vent, the rotating member comprises a horizontal pivot, a first shield plate extending up from a top side of the pivot, and a second shield plate heavier than the first shield plate and extending down from a bottom side of the pivot, opposite ends of the pivot are rotatably connected to midpoints of opposite sides of the frame, and upon a condition that the gravity of the second shield plate is not overcome by an airflow passing through the vent, the gravity of the second shield plate causes the rotating member to rotatably stay in a position where the second shield plate vertically blocks a lower half of the vent and the first shield plate vertically blocks an upper half of the vent.

7. The electronic device of claim 6, wherein the first and second shield plates are symmetrical about the pivot, and are arranged substantially on a same plane.

8. The electronic device of claim 7, wherein the vent defines a substantially circular cross section, opposite ends of the first and second shield plates are arc-shaped, and are arranged on an arc of a circle centered around a midpoint of the pivot.

9. The electronic device of claim 8, wherein the opposite ends of the first and second shield plates abut inner surfaces of the opposite sides of the frame, in response to the rotating member vertically blocking the vent.

10. The electronic device of claim 6, wherein a perpendicular distance between a top side of the first shield plate and a bottom side of the second shield plate is not more than a perpendicular distance between a front end and a rear end of the frame.

11. An electronic device, comprising:
a chassis;
a standard fan mounted in the chassis and comprising a first frame, the first frame defining a first vent through a front end and a rear end of the first frame; and
an air dam module mounted to the front end of the first frame, the air dam module comprising a second frame defining a second vent aligning with the first vent, wherein the second frame has the same shape and size as the first frame, the air dam module comprises a rotating member received in the second vent, the rotating member comprises a horizontal pivot, a first shield plate extending up from a top side of the pivot, and a second shield plate heavier than the first shield plate and extending down from a bottom side of the pivot, opposite ends of the pivot are rotatably connected to midpoints of opposite sides of the second frame, upon a condition that the gravity of the second shield plate is not overcome by an airflow passing through the vent, the gravity of the second shield plate causes the rotating member to rotatably stay in a position where the second shield plate vertically blocks a lower half of the vent and the first shield plate vertically blocks an upper half of the vent, and wherein the second shield plate rotates forward 90 degrees, and the first shield plate rotates backward 90 degrees, in response to the standard fan blowing air towards the air dam module.

12. The electronic device of claim 11, wherein the first and second shield plates are symmetrical about the pivot, and are arranged substantially on a same plane.

13. The electronic device of claim 12, wherein each of the first and second vents defines a substantially circular cross section, opposite ends of the first and second shield plates are arc-shaped, and are arranged on an arc of a circle centered around a midpoint of the pivot.

14. The electronic device of claim 13, wherein the opposite ends of the first and second shield plates abut inner surfaces of the opposite sides of the second frame, in response to the rotating member vertically blocking the second vent.

15. The electronic device of claim 11, wherein a perpendicular distance between a top side of the first shield plate and a bottom side of the second shield plate is not more than a perpendicular distance between a front end and a rear end of the second frame.
